(19) United States
(12) Patent Application Publication
(10) Pub. No.: US 2005/0127895 A1
(43) Pub. Date: Jun. 16, 2005

(54) Current sensor wire clamp

(75) Inventor: Kenneth W. Rittmann, Kokomo, IN (US)

Correspondence Address: Jay G. Taylor;ICE MILLER, One American Square, Box 82001, Indianapolis, IN, 46282-0200, US

(73) Assignee: Functional Devices, Inc., Russiaville, IN (US)

(21) Appl. No.: 11/010,025

(22) Filed: Dec. 10, 2004

Related U.S. Application Data
(60) Provisional application No. 60/528,449, filed on Dec. 10, 2003.

(51) Int. Cl. G01R 31/08

(52) U.S. Cl. 324/117 R

(57) ABSTRACT

A current sensor includes a housing having a face and sidewalls. A channel is formed in the housing to allow a conductor to pass therethrough. A clamp is also located upon the housing, including a jaw having a cable engagement surface. A pawl is positioned upon an edge of the jaw and is designed to engage notches on the face of the housing. The jaw may be rotated upon the face of the housing such that the cable engagement surface moves perpendicularly across the axis of the channel. When a cable is located in the channel, the jaw may be rotated clockwise and placed snugly against the cable. If the flange is moved away from the face, the pawl is released from the notches, and the jaw may rotate freely, thereby allowing the cable to be released from the clamp.

### PRIORITY

This application claims priority to U.S. Provisional Patent Application 60/528,449, filed Dec. 10, 2003.

### BACKGROUND

Individuals that work with electrical wiring and circuits are often interested in knowing the amount of electrical current flowing through a particular conductor. Convenient tools for measuring the current flowing through a conductor include the Hall effect current sensor, the toroidal core current sensor and split core sensors (collectively, the split core sensors and toroidal core sensors are also known as “current transformers”). Current transformers and Hall effect devices are electromagnetic sensors that measure current based upon the principle that a current carrying conductor produces a magnetic field.

With reference to FIG. 6, a typical prior art current sensor includes a housing 110 with a channel 118 formed therethrough. A current transformer (not shown) is positioned within the housing and surrounds the channel 118. A toroidal core may be positioned around the channel 118 within the housing 110. The current transformer is connected to leads designed to carry a current to an analyzer. Alternatively, a toroidal core current sensor may comprise a toroidal coil wound around the core.

When utilizing these current sensors, the technician typically threads the cable or other conductor carrying the current to be tested through the channel formed in the housing. When alternating current flows through the cable, the changing magnetic field created by the alternating current induces a current on the current transformer. This current flowing through the current transformer is related to the current flowing through the conductor. The current flowing through the current transformer may be analyzed for its relationship to the current flowing through the cable. For example, to take a correct reading using Hall effect current sensors, the current sensor needs to remain relatively stationary with respect to the cable from which current is being measured, and it is important to keep the orientation of the Hall effect sensor consistent with respect to the wire. Most prior art current sensors require the technician to hold the current sensor stable upon the cable to make sure that it remains stationary and in the proper orientation. Alternatively, the technician can place the current sensor on the ground or hang the current sensor from the cable and try to make sure that the cable remains stationary when a reading is taken. Unfortunately, this is not easily accomplished, especially if the cable will be prone to movement as the technician works on and tests the electrical circuit that comprises the cable. Therefore, it would be desirable to provide a Hall effect sensor that can maintain its position relative to the cable without assistance from a technician.

Additionally, a Hall effect sensor may also be permanently attached to a particular cable to continuously monitor the current passing through the cable, with the Hall effect sensor in communication with a monitoring device. Therefore, in circumstances where the Hall effect sensor is in communication with a monitoring device, a technician is not available to maintain the position of the sensor in relation to the cable. For all current transformers and Hall effect sensors, it is often desirable to take a sensor reading with the current sensor suspended upon a vertical hanging or inclined cable. If the current sensor is not retained in place upon the cable, the current sensor may slide down the cable and next to other equipment that may interfere with the reading of the current sensor, or the orientation of the sensor may not be ideal. Accordingly, it would be advantageous to provide a current sensing device that may be secured to a cable without placing undue tension on the cable. Further, it is desirable to provide a current sensing device that may be releasably secured to a cable without the need for a tool to disengage the cable, thereby allowing a technician to remove the sensor from the cable after testing is complete.

### SUMMARY

The embodiments of the present invention relate to an apparatus for sensing current in a wire or cable, and specifically to an apparatus that is capable of securing itself in a proper orientation to the wire or cable it is sensing without additional support from a technician. In particular, one embodiment of the present invention relates to a current sensor for sensing current in a wire. The current sensor in this embodiment comprises a housing that has a channel through the channel being large enough so that a wire can fit through the channel; and a core inside the housing, the core positioned so that the core surrounds the channel. The sensor further comprises a jaw rotatably mounted to the housing, the jaw attached to the housing by a pivot pin. The jaw is operable to reduce the size of the channel by rotating the jaw in one direction. Additionally, the jaw has a pawl that can engage a number of notches that are on the face of the housing, the pawl and notches operable to allow movement of the jaw in one direction, but restrict movement in the opposite direction.

Optionally, the pawl of the current sensor may also comprise a flange operable to disengage the pawl from a notch when an upward force is applied to the flange. Further, the upward force may be applied without the aid of a tool by using, for example, a finger or other digit. Further, the jaw may operably rotate at an angle perpendicular to the axis of a wire within the channel, and the jaw may engage the wire without penetrating an insulating sheath around the wire. In at least one embodiment, the jaw may comprise a convex or concave surface.

In a second embodiment of the present invention, a current sensor for sensing current in a wire includes a housing having a channel therethrough of a size large enough to accommodate a wire. The channel would pass through the housing, and a core would surround the channel. Further, the current sensor would have a core surrounding the channel, and a jaw mounted to rotate about a pivot pin. The jaw would be operable to reduce the size of the channel or a channel opening as the jaw is rotated about he the pivot pin. The jaw would also have a pawl operable to engage several notches located on a face of the housing, with the pawl further comprising a flange operable to disengage the pawl from a notch when upward force is applied to the flange. Thus, when upward force is applied to the flange, the jaw is allowed to move in both directions about the pivot pin.

Optionally, the current sensor of the second embodiment could have a jaw that rotates at an angle perpendicular to the axis of a wire within the channel. Another option of this embodiment includes the ability for jaw to engage the wire without perforating an insulating sheath around the wire.

A third embodiment of the present invention is a current sensor for sensing current in a wire comprising a housing having a channel, with the channel having at least one open side that allows a wire to be inserted into the channel without breaking a complete circuit. Further, to allow the channel to have at least one open side, the sensor has a core comprising at least two portions. The two portions of the core are positioned around the closed side of the channel through its center when the at least two portioned are aligned to form a continuous loop. Additionally, the sensor includes a slidable housing cover that can operate to allow the at least two portions of the core to be moved relative to one another so that the channel is accessible from at least one side when the housing is placed in a first position, and operable to allow full contact between the first and second core portions to form a continuous loop when the housing is in a second position. Moreover, the sensor includes a jaw rotatably mounted to the housing about a pivot pin so that the jaw can reduce the size of at least one opening of the channel as the jaw is rotated about the pivot pin. Finally, the jaw includes a pawl mounted thereon and operable to engage the several notches located on a face of the housing, with the pawl further including a flange operable to disengage the pawl from the notches when upward force is applied to the flange. When upward force is applied to the flange, the jaw may be moved in both directions about the pivot pin.

Optionally, the flange of current sensor of this third embodiment may be manually operable to disengage the pawl without the aid of a tool. Additionally, a the jaw may rotate in a plane perpendicular to a longitudinal axis of the wire running through the channel.

According to a fourth embodiment of the present invention, a current sensor for sensing current in a wire may include a housing having a channel formed therethrough, with that channel having at least one open side that allows a wire to be placed within the channel without breaking a completed circuit. Further, the sensor includes a Hall effect sensor within the housing, operable to sense the current of the wire within the channel. Further, the sensor includes a jaw rotatably mounted to the housing by a pivot pin. The jaw is operable to engage a wire within the channel so that the wire is positioned against an inside wall of the channel as the jaw is rotated about the pivot pin. Further, the jaw includes a pawl mounted to the jaw and operable to engage a plurality of notches located on a face of the housing, with the pawl further comprising a flange operable to disengage the pawl from the notches when an upward force is applied to the flange, thereby allowing movement of the jaw in both directions about the pivot pin.

### BRIEF DESCRIPTION OF THE DRAWINGS

FIG. 1 shows a side plan view of one embodiment of a Current Sensor Wire Clamp;

FIG. 2 shows a perspective view of the Current Sensor Wire Clamp of FIG. 1;

FIG. 3 shows an enlarged cross-sectional view of a pawl located on the Current Sensor Wire Clamp along line III-III of FIG. 1;

FIG. 4 shows a perspective view of an alternative embodiment of the Current Sensor Wire Clamp of FIG. 5 with the moveable bar positioned in the channel; and

FIG. 5 shows a top plan view of an alternative embodiment of a Current Sensor Wire Clamp with a moveable bar removed from the channel;

FIG. 6 shows a perspective view of a typical prior art current sensing device.

FIG. 7 shows a top plan view of an alternative embodiment of the Current Sensor Wire Clamp wherein the sensor employed is a Hall effect sensor.

FIG. 8 shows a perspective view of an alternative embodiment of the Current Sensor Wire Clamp wherein the sensor employed is a Hall effect sensor.

### DESCRIPTION

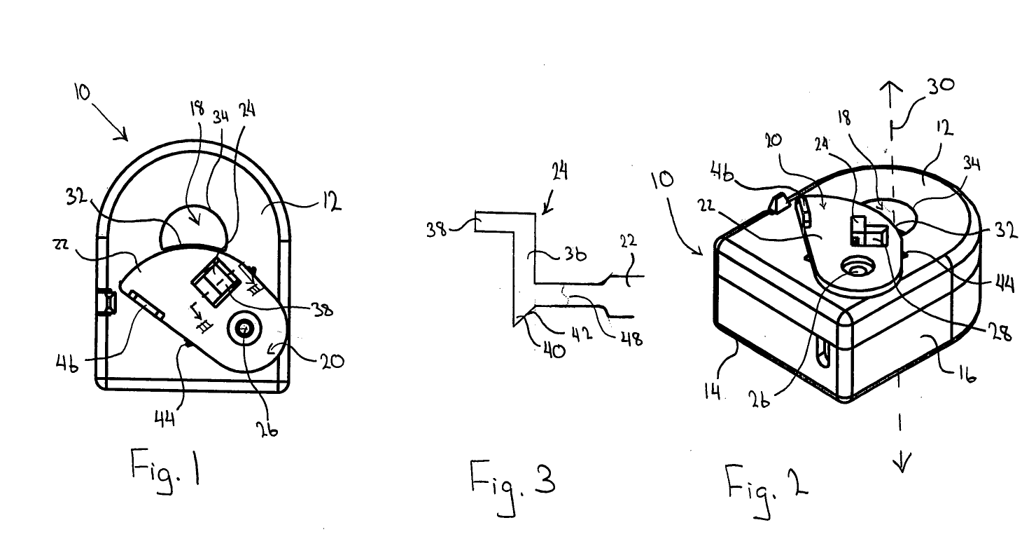

FIGS. 1 and 2 show one embodiment of a current sensor wire clamp including a housing and a cam device for securing the current sensor to a cable. The current sensor housing 10 includes a front face 12 and a back surface 14 with sidewalls 16 extending therebetween. The face 12 and back surface 14 are substantially parallel. The sidewalls 16 are substantially perpendicular to the face 12 and the back surface 14.

A channel 18 is formed through the housing 10 from the face 12 to the back surface 14. The channel 18 may be substantially cylindrical in shape, and is designed to receive a cable or other conductor carrying current to be measured. The central axis of the channel defines an axis 30 where the cable is intended to be inserted. As is standard in the art, a current transformer (not shown) is positioned within the housing 10 such that the current transformer surrounds the channel 18, yet remains encased within the housing. This current transformers may take many embodiments, such as a core and toroidal coil, a core and bobbin coil, or other current transformers used in the art.

A clamp 20 is positioned upon the face 12 of the housing 10. The clamp 20 comprises a jaw 22 that is rotatably connected to the face 12 of the housing by a pivot pin 26. The jaw 22 is rotatable around the pivot pin 26 such that the jaw 22 rotates substantially parallel to the face 12 and substantially perpendicular to the axis 30. The jaw 22 is generally curvilinear in its shape, with a sloping cable engagement surface 32, and jaw 22 may also take the shape of a cam, or may be convex, or concave in nature. Cable engagement surface 32 slopes to allow greater retention of the wire within the channel when jaw 22 is engaging wire coating and wedging the wire against the interior walls of channel 18. When the jaw 22 is rotated about the pivot pin 26, the sloping cable engagement surface 32 gradually decreases the size of the opening 34 of channel 18 as it bisects the axis 30. The jaw 22 is slightly thicker at the cable engagement surface 32 than other portions of the jaw 22. The jaw 22 is secured by the pivot pin point 26 which may comprise a screw, bolt, rivet or other fastening means that allows the jaw 22 to pivot freely.

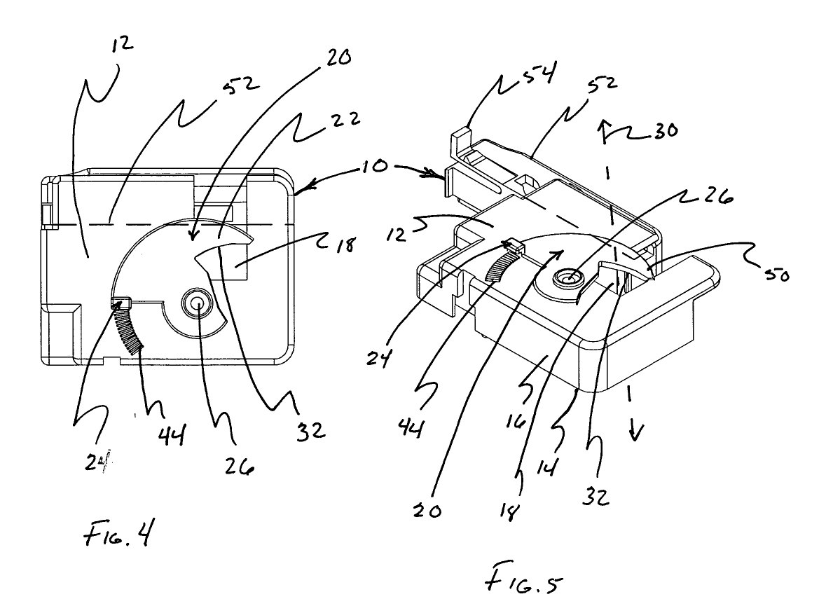

A pawl 24 is positioned in a slot 28 formed in jaw 22. As shown in FIG. 3, the pawl 24 includes a first arm 48 that extends outward from the jaw 22 within the slot 28 and a second arm 36 that extends substantially perpendicularly to first arm 48 upward from the surface of the jaw 22. A flange 38 extends substantially perpendicularly from the second arm 36. The pawl 24 also includes a tip 40 with a sloped surface 42 that generally forms an acute angle with respect to the arm 48. The pawl 24 is allowed to pivot with respect to the jaw 22 as the first arm 48 flexes up and down with respect to the jaw 22.

A series of notches 44 (partially obstructed) are formed on the surface of the face 12 of the housing and form a ratchet surface designed to engage the tip of the pawl. The notches 44 are spaced radially upon the face 12 of the housing concentric with the pivot pin. Each notch is separated from the adjacent notch to allow the tip 40 of the pawl 24 to enter the space between the notches. When the tip 40 of the pawl 24 engages the notches 44, the jaw 22 may be rotated clockwise, but counterclockwise rotation is prevented. However, upward movement of the flange 38, away from the jaw 22 will cause the tip 40 of the pawl 24 to disengage the notches 44, and the jaw 22 may then be rotated either clockwise or counterclockwise around the pivot pin 26. A small lip 46 is also positioned upon the jaw 22 such that it extends above the surface of the jaw 22. The lip 46 is useful to assist with rotation of the jaw 22 around the pivot pin 26, as it provides a larger surface that may be grasped by the user or pushed either clockwise or counterclockwise.

In operation, an electrical technician interested in knowing the current flowing through a cable first rotates the jaw 22 in a clockwise manner so the jaw 22 does not block the opening 34 to the channel 18. The technician then inserts the cable through the channel 18 of the housing 10 and again rotates the jaw 22 clockwise until the cable engagement surface 32 is firmly positioned against the cable, causing an opposing pressure on the conductor by the channel wall 18. Because of the ratchet action between the notches 44 on the face 12 of the housing 10 and the pawl 24, the jaw 22 is prevented from moving in the counterclockwise direction and firmly clamps the current sensor to the cable. With the current sensor firmly joined to the cable, the technician is free to take current measurements, knowing that the current sensor will remain in place upon the cable.

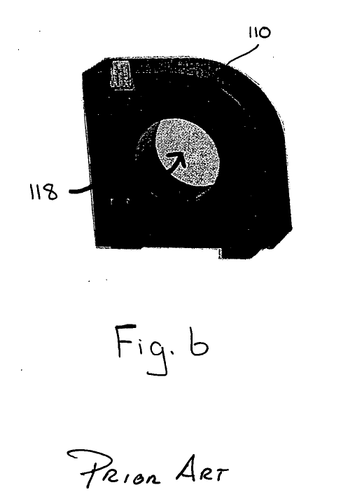

An alternative embodiment is shown in FIGS. 4 and 5. This alternative embodiment of the invention is generally described using the same reference numerals that were used to refer to the embodiment associated with FIGS. 1-3. As shown in FIG. 4, the current sensor includes a housing 10 having a face 12 and sidewalls 16. A channel 18 is formed through the housing. Unlike the embodiment shown in FIGS. 1-3, this channel 18 is not enclosed and is a U-shaped indentation in the side of the housing. A moveable bar 52 can be slid to close channel 18 once a wire is inserted. Accordingly, the coil and any core positioned within the housing surrounding the channel is U-shaped and the moveable bar 52 completes a toroidal assembly. The moveable bar 52 includes a portion of the magnetic core and when the bar 52 is moved into place in the channel 18 (as shown in FIG. 5), the magnetic core of the current sensor is completed. The moveable bar 52 may take a number of different forms such as a sliding bar or hinged bar. This core configuration comprises more than one portion that may be moved in relation to one another, and thereafter moved back into position so that the two portions are brought back into physical contact with one another to allow the current sensor to operate.

In operation, when the U-shaped channel is accessible (as shown in FIG. 5), the sensor core is open, and the current sensor is inoperable. However, having the channel accessible, the current sensor can be placed over a wire without having to cut the wire and re-establish the wire's connection to complete the circuit. Once the wire is placed within the U-shaped channel along the axis 30, sliding bar 52 can be placed in the closed position as shown in FIG. 4 to allow the current sensor core to surround the wire and determine the current flowing through the wire. When in the closed position, the core is complete, and the sliding bar 52 is snapped into a locked position, as squeeze locks 54 snap into corresponding reliefs (not shown) in housing 10. Sliding bar 52 can then be released by placing opposing force on the squeeze locks 54 and pulling sliding bar away from the closed position. Therefore, the current sensor of the present embodiment can be applied to a wire without disassembling an existing circuit by simply disengaging bar 52 to expose U-shaped channel 18, sliding the wire into the channel, and closing bar 52 as shown in FIG. 4.

Additionally, it is contemplated that this embodiment of the current invention can be stabilized upon the wire to allow for accurate current sensing without requiring the technician to hold the sensor in place. With reference to FIGS. 4 and 5, a clamp 20 is also located upon the housing, including a jaw 22 having a cable engagement surface 32. This jaw 22 is generally formed as a portion of a circle, and includes a claw-like protuberance 50 that forms the cable engagement surface 32. A pawl 24 is positioned upon an edge of the jaw 22 and includes an arm 36 with an associated flange 38, as well as a tip (not shown) similar to tip 40 shown in FIG. 3, that is designed to engage notches 44 located on the face 12 of the housing. The notches on the surface of the face are dimensioned and are generally radially positioned concentric with a pivot pin 26 of the jaw 22. The jaw 22 may be rotated upon the face 12 of the housing 10 such that the cable engagement surface 32 moves perpendicularly across the axis 30 of the channel. When a cable is located in the channel 18, the jaw 22 may be rotated clockwise and placed snugly against the cable, causing an opposing pressure on the conductor by the wall of channel wall 18, but counterclockwise rotation of the jaw 22 is prohibited by the ratchet effect formed between the pawl tip and the notches 44. If the flange 38 is moved away from the face (for example by a technician pulling upward on the flange with his finger), the pawl tip is released from the notches 44, and the jaw 22 may rotate freely, thereby allowing the cable to be released by rotating the jaw 22 in a counterclockwise rotation.

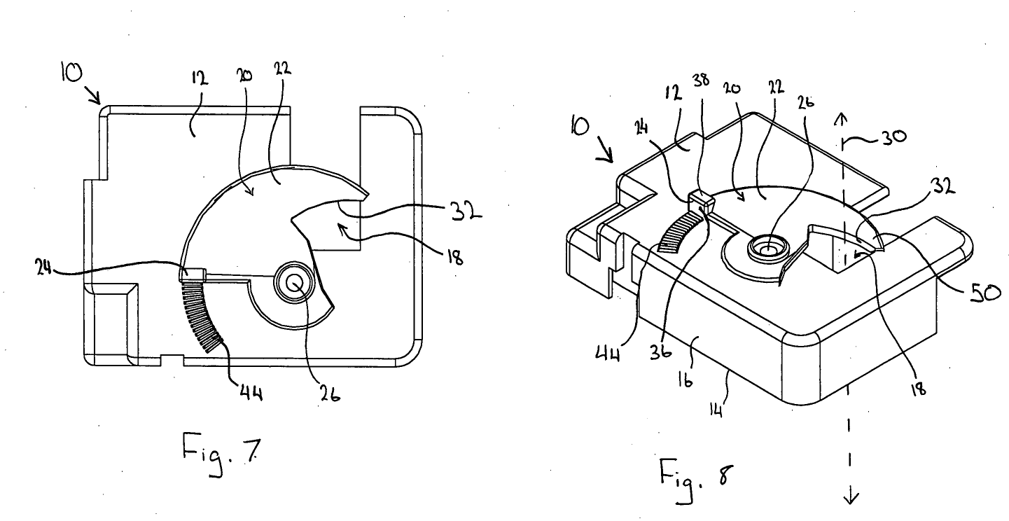

Referring now to FIGS. 7 and 8, another embodiment of the present invention contemplates the use of a Hall effect sensor with housing 10. This alternate embodiment of the invention is generally described using the same reference numerals that were used to refer to the embodiment associated with FIGS. 4 and 5, and this alternate embodiment resembles the previous embodiment with the exception that there is no need for sliding bar 52 due to the fact that a Hall effect sensor, such as the Hall plate sensor supplied by Micronas Technology Group, located at Technopark Technoparkstrasse 1, CH-8005 Zurich Switzerland, does not require the use of a core that surrounds the wire to be sensed. Instead, the Hall effect sensor (not shown) within housing 10 simply should be placed in an orientation so that the Hall plate is maintained so that its flat plate surface is kept parallel to the wire to be sensed when jaw 22 is closed upon the wire.

With reference to FIGS. 7 and 8, a clamp 20 is also located upon the housing, including a jaw 22 having a cable engagement surface 32. This jaw 22 is generally formed as a portion of a circle, and includes a claw-like protuberance 50 that forms the cable engagement surface 32. A pawl 24 is positioned upon an edge of the jaw 22 and includes an arm 36 with an associated flange 38, as well as a tip (not shown) similar to tip 40 shown in FIG. 3, that is designed to engage notches 44 located on the face 12 of the housing. The notches on the surface of the face are dimensioned and are generally radially positioned concentric with a pivot pin 26 of the jaw 22. The jaw 22 may be rotated upon the face 12 of the housing 10 such that the cable engagement surface 32 moves perpendicularly across the axis 30 of the channel. When a cable is located in the channel 18, the jaw 22 may be rotated clockwise and placed snugly against the cable, causing an opposing pressure on the cable by the wall of channel wall 18, but counterclockwise rotation of the jaw 22 is prohibited by the ratchet effect formed between the pawl tip and the notches 44. If the flange 38 is moved away from the face (for example by a technician pulling upward on the flange with his finger), the pawl tip is released from the notches 44, and the jaw 22 may rotate freely, thereby allowing the cable to be released by rotating the jaw 22 in a counterclockwise rotation. Of course, housing 10, channel 18, and jaw 22 may take many forms in this embodiment, with the aim that jaw 22 places wire against the inside wall of channel 18 so that the Hall effect sensor (not shown) within housing 10 remains stationary and in proper orientation with the wire or cable being sensed. Therefore, channel 18 may take the shape of a curved wall upon which jaw 22 traps a cable against, two angled walls wherein jaw 22 traps the wire within the angle formed by the intersection of the two walls, or a flat surface against which jaw 22 engulfs the cable against, limiting movment of the cable by the engaging surface 32 of jaw 22, or several other shapes and configurations that will be apparent to one of ordinary skill in the art.

Although the present invention has been described in considerable detail with reference to certain preferred versions thereof, other versions are possible. For example the clamp could include multiple jaws instead of a single jaw. In addition, the jaw 22 need not rotate about a single pivot pin 26, but could be designed to move back and forth in a linear fashion. Therefore, the spirit and scope of the invention should not be limited to the description of the preferred versions contained herein.

1. A current sensor for sensing current in a wire comprising:
a. a housing;
b. a channel, formed through the housing; the channel being of a size large enough to accommodate a wire;
c. a core within the housing positioned around the channel; and
d. a jaw rotatably mounted to the housing by a pivot pin, the jaw operable to reduce the size of the channel as the jaw is rotated about the pivot pin, the jaw further comprising a pawl operable to engage a plurality of notches formed on a face of the housing so that the jaw can be moved in one direction to reduce the size of the channel, but prevented from moving in the opposite direction until the pawl is disengaged from the notches.

2. The current sensor of claim 1 wherein the pawl further comprises a flange operable to disengage the pawl from a notch when upward force is applied to the flange, thereby allowing movement of the jaw in both directions about the pivot pin.

3. The current sensor of claim 2, wherein the upward force is applied without a tool.

4. The current sensor of claim 1, wherein the jaw rotates at an angle perpendicular to the axis of a wire within the channel.

5. The current sensor of claim 4, wherein the jaw engages the wire without penetrating an insulating sheath around the wire.

6. The current sensor of claim 1, wherein the jaw comprises a convex surface.

7. The current sensor of claim 1, wherein the jaw comprises a concave surface.

8. A current sensor for sensing current in a wire comprising:
a. a housing having a channel formed therethrough of a size large enough to accommodate the wire, the channel passing through the housing;
b. a core surrounding the channel;
c. a jaw mounted for rotation about a pivot pin, the jaw operable to reduce the size of the channel as the jaw is rotated about the pivot pin; and
d. the jaw further comprising a pawl operable to engage a plurality of notches located on a face of the housing, the pawl further comprising a flange operable to disengage the pawl from a notch when upward force is applied to the flange, thereby allowing movement of the jaw in both directions about the pivot pin when an upward force is applied.

9. The current sensor of claim 8, wherein the jaw rotates at an angle perpendicular to the axis of a wire within the channel.

10. The current sensor of claim 8, wherein the jaw engages the wire without perforating an insulating sheath around the wire.

11. A current sensor for sensing current in a wire comprising:
a. a housing having a channel formed therethrough, the channel having at least one open side to permit the wire to be inserted into the channel without breaking a completed circuit;
b. a core comprising at least two portions, one portion positioned around the closed side of the channel through its center when the at least two portions are aligned to form a continuous loop;
c. a slidable housing cover operable to allow the at least two portions of the core to be moved relative to one another so that the channel may be accessible from at least one side when the housing is placed in a first position, and operable to allow full contact between the first and second portions to form a continuous loop when the housing is in a second position;
d. a jaw rotatably mounted to the housing about a pivot pin, the jaw operable to reduce the size of at least one opening of the channel as the jaw is rotated about the pivot pin; and
e. a pawl mounted to the jaw and operable to engage a plurality of notches located on a face of the housing, the pawl further comprising a flange operable to disengage the pawl from the notches when upward force is applied to the flange, thereby allowing movement of the jaw in both directions about the pivot pin.

12. The current sensor of claim 11, wherein the flange is manually operable to disengage the pawl without the aid of a tool.

13. The current sensor of claim 11, wherein a plane of rotation of the jaw is perpendicular to a longitudinal axis of the wire running through the channel.

14. A current sensor for sensing current in a wire comprising:
a. a housing;
b. a Hall effect sensor within the housing, operable to sense the current of the wire in proximity to the housing;
c. a jaw rotatably mounted to the housing about a pivot pin, the jaw operable to engage a wire within proximity of the housing; and
d. a pawl mounted to the jaw and operable to engage a plurality of notches located on a face of the housing, the pawl further comprising a flange operable to disengage the pawl from the notches when upward force is applied to the flange, thereby allowing movement of the jaw in both directions about the pivot pin.
